(19) United States
(12) Patent Application Publication
(10) Pub. No.: US 2026/0106615 A1
(43) Pub. Date: Apr. 16, 2026

(54) BOOTSTRAP CAPACITANCE CHARGING SCHEME FOR GALLIUM NITRIDE BASED BRIDGE DRIVER

(71) Applicant: TEXAS INSTRUMENTS INCORPORATED, Dallas, TX (US)

(72) Inventors: Vipul Singhal, Bangalore (IN); Amal Kumar Kundu, Bangalore (IN); Anant Kamath, Bangalore (IN); Pranav K A, Bengaluru (IN)

(21) Appl. No.: 19/219,517

(22) Filed: May 27, 2025

(30) Foreign Application Priority Data
Oct. 11, 2024 (IN) 202441077214
Oct. 22, 2024 (IN) 202441077217

(51) Int. Cl. H03K 17/687; H02M 3/07

(52) U.S. Cl. CPC H03K 17/6872; H02M 3/07; H03K 2217/0063; H03K 2217/0072

(57) ABSTRACT

An apparatus comprises a capacitor connected between a bootstrap supply terminal (HB) and a switching terminal (HS) of a bridge driver. The apparatus further comprises an NMOS transistor having its drain terminal and cathode of its body diode both connected to the bootstrap supply terminal. The apparatus further comprises a pair of PMOS transistors coupled in parallel with shared source and drain terminals, wherein their shared source terminal connects to a first power supply (VDD) at a first power supply terminal, wherein their shared drain terminal connects in series to a source terminal of the NMOS transistor. The apparatus further comprises a charge pump capable of generating a second power supply (VCP) at a second power supply terminal, wherein the second power supply is capable of charging the capacitor via the NMOS transistor and the pair of PMOS transistors at a higher voltage than the first power supply.

### RELATED APPLICATION

This application claims priority to India Provisional Patent Application No. 202441077214, filed Oct. 11, 2024, and entitled “Bootstrap Capacitance Charging Scheme For Gallium Nitride Based Bridge Driver,” which is hereby incorporated by reference.

This application also claims priority to India Provisional Patent Application No. 202441077217, filed Oct. 22, 2024, and entitled “Zero Voltage Sense (ZVS), Zero Current Sense (ZCS) And Over Current Protection (OVP) On Silicon Die For GaN FET,” which is hereby incorporated by reference.

### BACKGROUND

Bridge drivers are specialized integrated circuits (ICs) designed to efficiently and reliably drive field-effect transistors (FETs) in half-bridge configurations. For non-limiting examples, the FETs driven by the bridge drivers can be but are not limited to Gallium Nitride (GaN) FETs and metal-oxide-semiconductor (MOS) FETs. A bridge driver typically has its high-side-domain (HSD) driven by charges stored in a bootstrap capacitor (C_{BOOT}).

The bootstrap capacitor C_{BOOT} has to be charged from an external power supply (VDD) in a controlled manner in order to drive the HSD of the bridge driver. This is done by a bootstrap capacitance charger. Current bootstrap capacitance charging solutions often do not enable fast charging of the bootstrap capacitor and do not have safeguards against a reverse recovery charge (QRR) build-up that accumulates within the body diode of the FET during switching, leading to potential losses and issues like spikes in voltage and shoot-through current.

### SUMMARY

In an example, an apparatus comprises a capacitor connected between a bootstrap supply terminal (HB) and a switching terminal (HS) of a bridge driver. The apparatus further comprises an NMOS transistor having its drain terminal and cathode of its body diode both connected to the bootstrap supply terminal. The apparatus further comprises a pair of PMOS transistors coupled in parallel with shared source and drain terminals, wherein their shared source terminal connects to a first power supply (VDD) at a first power supply terminal, wherein their shared drain terminal connects in series to a source terminal of the NMOS transistor, and wherein cathodes of body diodes of the pair of PMOS transistors connect to the first power supply terminal. The apparatus further comprises a charge pump capable of generating a second power supply (VCP) at a second power supply terminal, wherein the second power supply is capable of charging the capacitor via the NMOS transistor and the pair of PMOS transistors at a higher voltage than the first power supply.

In another example, an apparatus comprises a capacitor connected between a bootstrap supply terminal (HB) and a switching terminal (HS) of a bridge driver. The apparatus further comprises a charge pump capable of generating a second power supply at a higher voltage than a first power supply at a power supply terminal (VCP), wherein the second power supply is capable of charging the capacitor via a NMOS transistor and a pair of PMOS transistors connected in series with the NMOS transistor. The apparatus further comprises a control logic capable of controlling charging of the capacitor via the pair of PMOS transistors.

In another example, a method comprises generating a second power supply at a higher voltage than a first power supply at a power supply terminal. The method further comprises utilizing the second power supply to charge a capacitor connected between a bootstrap supply terminal (HB) and a switching terminal (HS) of a bridge driver via a NMOS transistor and a pair of PMOS transistors connected in series with the NMOS transistor. The method further comprises generating a boot-on signal to start charging the capacitor. The method further comprises controlling charging of the capacitor via the NMOS transistor and the pair of PMOS transistors according to the boot-on signal.

### BRIEF DESCRIPTION OF THE DRAWINGS

FIG. 1 is an illustrative example of a schematic diagram of a bridge driver 100, which utilizes a bootstrap capacitance charger 120 to charge a bootstrap capacitor (C_{BOOT}) 114, in an example.

FIG. 2 depicts an example of a schematic diagram of the bootstrap capacitance charger 120 of the bridge driver 100 of FIG. 1, in an example.

FIG. 3 depicts examples of waveforms of the switching voltage V_{HS}, the boot-on signal, the gate voltage of the NMOS transistor, and gate voltages of the pair of PMOS transistors under buck mode operation, respectively.

FIG. 4 depicts an example of a schematic diagram of the ZVS unit 130 associated with each of the FETs of the bridge driver 100 of FIG. 1, in an example.

FIG. 5 depicts an example of a schematic diagram of the ZCS/OCP unit 132 associated with each of the FETs of the bridge driver 100 of FIG. 1, in an example.

### DETAILED DESCRIPTION

The same reference numbers or other reference designators are used in the drawings to designate the same or similar (either by function and/or structure) features.

Although GaN FETs are used as a non-limiting example of FETs to illustrate the proposed approach in the discussions below, same or similar approaches are equally applicable to other types of FETs such as MOSFETS as understood by one skilled in the art.

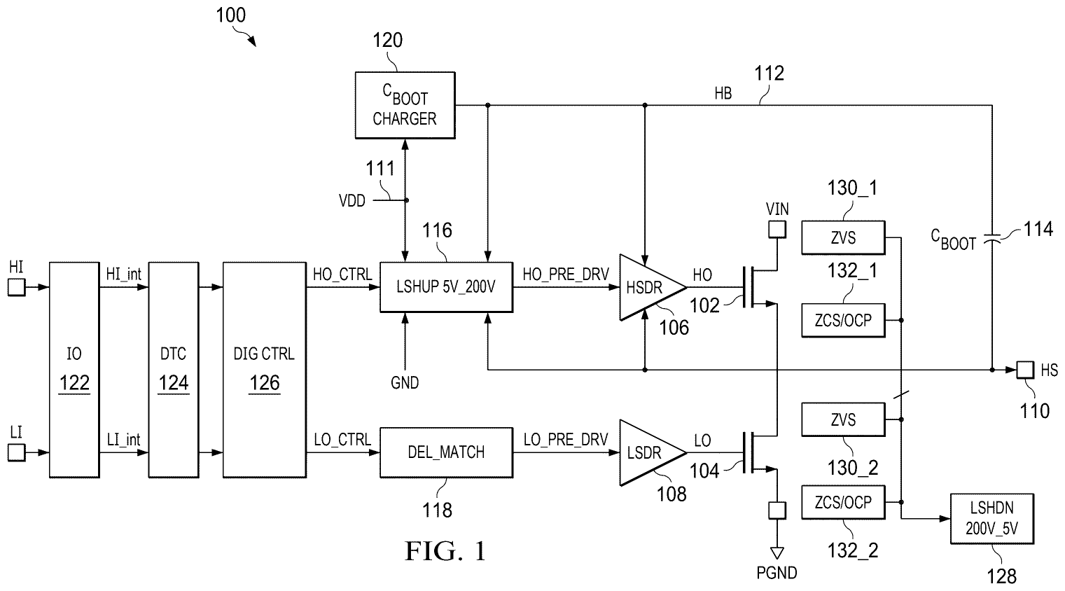

FIG. 1 is an illustrative example of a schematic diagram of a bridge driver 100, which utilizes a bootstrap capacitance charger 120 to charge a bootstrap capacitor (C_{BOOT}) 114. As shown in the example of FIG. 1, the bridge driver 100 comprises a high side driver 106 and a low side driver 108 capable of driving a pair of FETs 102 and 104, via output signals HO and LO, respectively. The pair of FETs 102 and 104 are serially connected between input voltage V_{IN} and ground P_{GND} with the drain terminal of FET 102 and the source terminal of FET 104 both connected to a switching terminal (HS or SW) 110. The switching voltage V_{HS} at the switching terminal 110 controls switching of the pair of FETs 102 and 104 on and off between the input voltage V_{IN} and the ground P_{GND}. In one example, the pair of FETs 102 and 104 are GaN FETs and the bridge driver 100 is a GaN-based bridge driver capable of controlling and driving the pair of GaN FETs in a half-bridge configuration.

In the example of FIG. 1, an input/output component 122 receives a high side input signal HI and a low side input signal LI, and converts these signals into an internal high side input signal HI_int and an internal low side input signal LI_int, respectively. A dead time controller (DTC) 124 receives the internal high side input signal HI_int and the internal low side input signal LI_int and generates two complementary signals with controlled dead time (when the switching voltage V_{HS} is negative) for the high side input signal HI_int and the internal low side input signal LI_int, respectively. A digital controller 126 is then capable of generating a high side output control signal HO_CTRL and a low side output control signal HO_CTRL by qualifying the two complementary signals from the DTC 124 based on one or more protection signals including but not limited to zero voltage sensing (ZVS) zero current sensing (ZCS), over current protection (OCP), etc.

On the high side domain (HSD) of the bridge driver 100, the bootstrap capacitor 114 is connected between the switching terminal 110 and a bootstrap supply terminal (HB) of the bridge driver 100. The bootstrap capacitance charger 120 accepts an external power supply (VDD) from power supply terminal 111 as its input, and provides a bootstrap supply voltage V_{HB} at the bootstrap supply terminal 112 as its output to charge the bootstrap capacitor 114. A voltage level up shifter (LSHUP) 116 is capable of receiving the high side output control signal HO_CTRL from the digital controller 126 and generate a high side pre-driver output signal HO_PRE_DRV to the high side driver 106 at a higher voltage (e.g., 5V to 200V) on the switching voltage V_{HS} and the bootstrap supply voltage V_{HB}. The high side driver 106 generates the high side output signal HO from the high side pre-driver signal HO_PRE_DRV to drive the high side FET 102.

On the low side domain (LSD) of the bridge driver 100, a delay matcher (DEL_MATCH) 118 is capable of receiving the low side output control signal LO_CTRL from the digital controller 126 and generate a low side pre-driver output signal LO_PRE_DRV that matches the delay of the path from high side input HI to the high side pre-driver output signal HO_PRE_DRV and the delay of the path from low side input LI to low side pre-driver output signal LO_PRE_DRV. The low side driver 108 generates the low side output signal LO from the low side pre-driver signal LO_PRE_DRV to drive the low side FET 104.

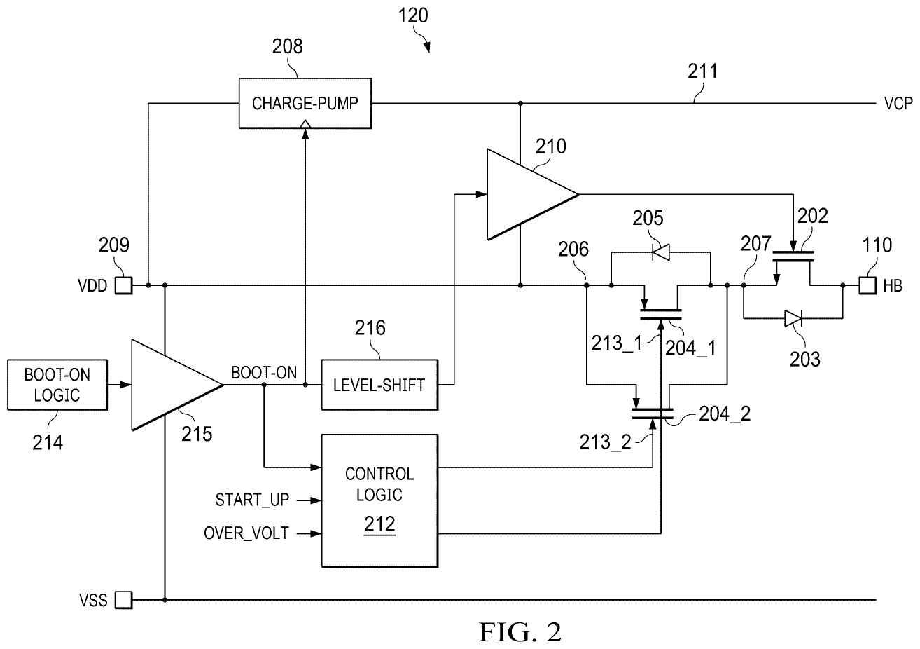

FIG. 2 depicts an example of a schematic diagram of the bootstrap capacitance charger 120 of the bridge driver 100 of FIG. 1. As shown in the example of FIG. 2, the bootstrap capacitance charger 120 includes an NMOS transistor 202 having its drain terminal and cathode of its body diode 203 both connected to the bootstrap supply terminal HB. In one example, the NMOS transistor 202 is a high-voltage NMOS (HV-NMOS) with voltage up to, e.g., 220V. In one example, the NMOS transistor 202 serves as a reverse-blocking FET that blocks reverse-recovery charge (QRR) to avoid a diode drop during charging of the bootstrap capacitor 114. The bootstrap capacitance charger 120 further comprises a pair of PMOS transistors 204_1 and 204_2 coupled in parallel with shared source terminal 206 and drain terminal 207, respectively. The shared source terminal 206 of the pair of PMOS transistors 204_1 and 204_2 connects to a first power supply VDD at a first power supply terminal 209, wherein their shared drain terminal 207 connects in series to the source terminal of the NMOS transistor 202. Cathodes of body diodes 205 of the pair of PMOS transistors 204_1 and 204_2 also connect to the first power supply terminal 209. In one example, the pair of PMOS transistors 204_1 and 204_2 serve as control FETs that control charging current to the bootstrap capacitor 114. The bootstrap capacitance charger 120 further comprises a charge pump 208 capable of generating a second/additional power supply VCP at a second power supply terminal 211, wherein the second power supply is utilized by a gate driver 210 to charge bootstrap capacitor 114 via the NMOS transistor 202 and the pair of PMOS transistors 204_1 and 204_2.

In one example, the bootstrap capacitance charger 120 further includes a control logic 212 capable of generating a control signal to drive gates 213_1 and 213_2 of the pair of PMOS transistors 204_1 and 204_2, respectively, to charge the bootstrap capacitor 114. In one example, the control logic 212 of the bootstrap capacitance charger 120 receives three input signals—an over voltage signal OVER_VOLT, a boot-on signal (BOOT-ON) generated by a boot-on logic 214 discussed below through a driver 215, and a charging start up signal START_UP. In one example, the control logic is capable of stopping the pair of PMOS transistors 204_1 and 204_2 from charging the bootstrap capacitor if there is an over voltage condition at the bootstrap capacitor 114 as indicated by the over voltage signal OVER_VOLT.

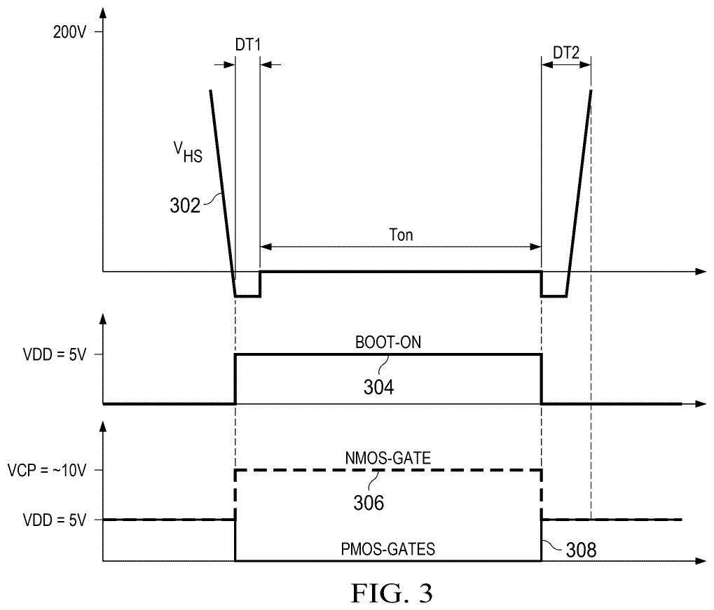

In one example, the bootstrap capacitance charger 120 further includes the boot-on logic 214 capable of generating the boot-on signal for charging the bootstrap capacitor 114. FIG. 3 depicts examples of waveforms of the switching voltage V_{HS} 302, the boot-on signal (BOOT-ON) 304, the gate voltage 306 of the NMOS transistor 202, and gate voltages 308 of the pair of PMOS transistors 204_1 and 204_2 under buck mode operation, respectively. As shown by FIG. 3, the boot-on signal 304 goes high/ON at beginning of a first dead time DT1 of the switching voltage V_{HS} 302 at the switching terminal 110, wherein the switching voltage V_{HS} 302 goes negative during the first dead time DT1. Note that the switching voltage V_{HS} 302 can go as-low-as −3V in case of GaN FETs. The boot-on signal 304 goes low at beginning of a second dead time DT2 of the switching voltage V_{HS} 302, wherein DT1 of the switching voltage V_{HS} 302 goes negative during the second dead time DT2. However, the boot-on signal 304 always remains low under over voltage condition at the bootstrap capacitor 114. The switching voltage V_{HS} 302 stays at low (e.g., 0V) during the time T_{ON} between the first dead time DT1 and the second dead time DT2, which turns on the high side FET 102 in the HSD of the bridge driver 100.

In one example, the boot-on logic 214 provides the boot-on signal 304 to the charge pump 208 (via the driver 215) to start charging the bootstrap capacitor 114. In one example, the bootstrap capacitance charger 120 further includes a level shifter 216 capable of receiving the boot-on signal 304 from the boot-on logic 214 as its input and generate a level-shifted version of the boot-on signal 306 to drive the gate of the NMOS transistor 202 via the gate driver 210 to charge the bootstrap capacitor 114. As shown by FIG. 3, the level shifter 216 shifts the voltage levels from VDD (e.g., 5V)-VSS (e.g., 0V) domain to VCP (e.g., 10V)-VDD domain. In one example, the control logic 212 is capable of receiving the boot-on signal 304 and generating the gate voltages 308 of the pair of PMOS transistors 204_1 and 204_2 to be the opposite of the boot-on signal 304, i.e., the gate voltages 308 are high when the boot-on signal 304 is low and verse versa.

In one example, a first PMOS transistor 204_1 and a second PMOS transistor 204_2 of the pair of PMOS transistors have different strength and/or threshold voltages. For a non-limiting example, the size of a strong PMOS transistor can be four times the size of a weak PMOS transistor. During normal operation, the gates of both the first PMOS transistor 204_1 and the second PMOS transistor 204_2 switch together as controlled by the gate voltages 308 shown in FIG. 3. However, there are some exceptions when only one of the pair of PMOS transistors 204_1 and 204_2 is turned on to charge the bootstrap capacitor 114 under certain circumstance. For example, during charging start-up when the charging start up signal is ON and the bootstrap capacitor 114 starts being charged from an uncharged state, only the weak PMOS transistor is turned ON while the gate of the Strong PMOS remains high. For another example, if there is an over voltage condition at the bootstrap capacitor 114 at any time, both PMOS gates are instantly driven high to stop further charging.

Because charging of the bootstrap capacitor 114 starts during DT1 when the boot-on signal is on (the switching voltage V_{HS} 302 is in the range of −2V to −3V), the approach described above enables much faster and efficient charging of the bootstrap capacitor 114. Furthermore, since the body-diode 203 of the NMOS transistor 202 is either shorted by the NMOS transistor 202 when the boot-on signal is high/on or open-circuited by the pair of PMOS transistors 204_1 and 204_2 when the boot-on signal is low/off, the body-diode 203 is never forward-biased. As such, there is no QRR build up during charging of the bootstrap capacitor 114, which ensures that the low-to-high transition of the switching voltage V_{HS} is smooth and fast. In addition, since charging of the bootstrap capacitor 114 is disabled during DT2 when the boot-on signal is low, the NMOS transistor 202 is firmly off before the rise of the switching voltage V_{HS}, hence protecting the rest of the bridge driver 100 from a transient high-voltage, which can be destructive. Since the approach described above does not have any special requirement for any silicon or GaN FET, makes it compatible with advanced and power-efficient technology terminals.

For power FETs, such as the FETs 102 and 104 in FIG. 1, pulsed drain current (IDM) operation, which refers to the maximum drain current the FETs can handle for a short pulse duration, improves efficiency and ease of design of the FETs. Zero voltage sense (ZVS) function, which detects when a voltage signal crosses the zero-voltage point (0V) and zero current sense (ZCS) function, which detects when current flowing through a circuit component reaches zero, help emulate an IDM operation for a power FET. In addition, over current protection (OCP), which prevents excessive current flow in the circuits, improves system reliability and protects the power FETs against unwanted short circuits. However, drain-source voltage sensing for a power FET, e.g., a GaN power FET, needs high voltage (e.g., up to 200V) blocking as well as a negative voltage tracking (e.g., <−2.5V), wherein negative voltage sense may turn-on the parasitic diode of the FETs to silicon substrate.

In the example of FIG. 1, the bootstrap capacitance charger 120 further includes a pair of ZVS units 130_1 and 130_2 each associated with one of the FETs 102 and 104, respectively, wherein each ZVS unit 130 is integrated on the silicon substrate/die and capable of detecting when the drain-source voltage Vds of the FET at its source terminal crosses the zero-voltage point. In one example, the ZVS unit 130 includes an insulated laterally-diffused metal-oxide semiconductor (LDMOS) device/component, which is a planar double-diffused MOSFET used for Vds sensing on silicon die. The ZVS unit 130 utilizes the LDMOS device as a sense-based protection circuit around the corresponding FET, wherein the insulated LDMOS allows to track negative voltage without loading the switching terminal 110 for a negative voltage tracking.

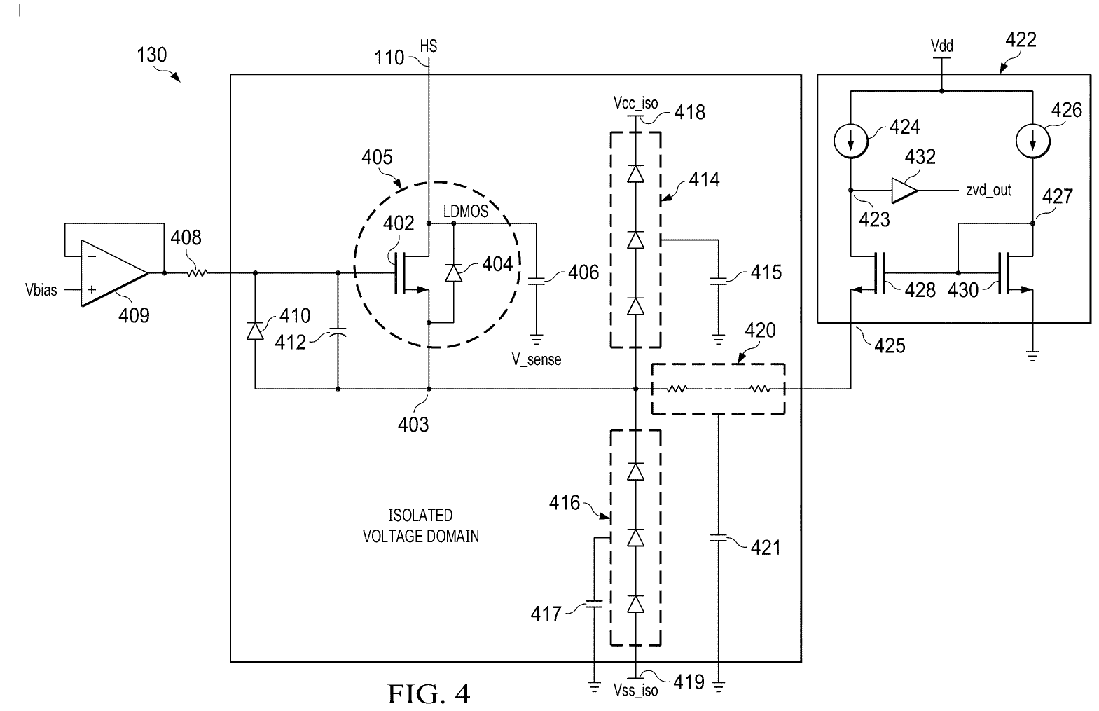

FIG. 4 depicts an example of a schematic diagram of the ZVS unit 130 associated with each of the FETs of the bridge driver 100 of FIG. 1. As shown in the example of FIG. 4, the ZVS unit 130 includes a LDMOS 402 with its drain terminal connected to the switching terminal (HS) 110 shown in FIG. 1 and its source terminal 403 being the voltage sensing terminal. In one example, the LDMOS 402 has a body-diode 404 between its drain and source terminal and a capacitor 406 coupled between the drain terminal of the LDMOS 402 and ground. In one example, the LDMOS 402 allows the switching voltage V_{HS} to swing up to −5V with respect to the substrate voltage Vss without loading the switching terminal 110. In one example, the LDMOS device 402 serves as a sense FET to sense a voltage Vsense at its source terminal 403 without any parasitic diode to silicon substrate.

As shown in the example of FIG. 4, the LDMOS 402 is insulated in an isolated voltage domain for immunity from electrostatic discharge (ESD) and isolation from other circuitry by high value resistances, e.g., resistor 408, from its gate terminal 405 and source terminal 403. In one example, all the components in isolated voltage domain are 5V components with suitable isolation. As shown in FIG. 4, the resistor 408 is in the input path of an amplifier 409 and allows the sense terminal 403 to swing well below the ground voltage. In one example, the amplifier 409 biases the gate of 405 with Vbias (e.g., ˜3V) generated inside the chip. In one example, the ZVS unit 130 includes a diode clamp 410, e.g., a Zener diode, between the gate terminal 405 to the source terminal 403 of the LDMOS 402 protects the LDMOS gate 405, wherein the diode clamp 410 limits voltage excursions by conducting when a specific reverse voltage (e.g., the Zener voltage) is reached, effectively clamping voltage at the gate terminal 405 of the LDMOS 402 at its current level. In one example, the ZVS unit 130 includes an additional capacitor 412 coupled between the gate 405 and source 403 of the LDMOS 402, wherein the capacitor 412 absorbs drain to gate coupling of the LDMOS 402 due to high dV/dt at the switching terminal 110.

In some cases, the sensed voltage V_sense at the source terminal 403 of the LDMOS 402 also needs suitable clamp to make the voltage detection faster. In one example, the ZVS unit 130 includes a first set 414 of one or more diodes coupled between a supply voltage Vcc_iso (e.g., 5V) at terminal 418 and the source terminal 403 as well as a capacitor 415 coupled between one of the diodes in the first set 414 and ground. In one example, the ZVS unit 130 further includes a second set 416 of one or more diodes coupled between the source terminal 403 and a Vss_iso (e.g., ground) at terminal 419 and as well as a capacitor 415 coupled between one of the diodes in the second set 416 and ground.

In the example of FIG. 4, the ZVS unit 130 includes a threshold resistor Rth 420 coupled between the sensing source terminal 403 and a current comparator 422. In one example, the threshold resistor Rth 420 is coupled to the ground via a capacitor 421. The bias current Ibias flowing from the current comparator 422 through the threshold resistor Rth 420 decides the negative ZVS threshold voltage for ZVS detection as (Ibias*Rth). In one example, the ZVS threshold can be programmed at much lower voltage (e.g., <−1V) to avoid false detection. As shown in the example of FIG. 4, the current comparator 422 includes a pair of bias current sources 424 and 426 as well as a pair of MOS transistors 428 and 430 with their gates connected to each other. The drain terminal 423 of the MOS transistor 428 connects to the bias current source 424. The source terminal 425 of the MOS transistor 428 connects to the threshold resistor Rth 420. The drain terminal 427 of the MOS transistor 430 connects to the bias current source 426 and to its gate as well with the source terminal of the MOS transistor 430 connects the ground. Under such configuration, the MOS transistor 428 is biased with the bias current source 426 such that its drain terminal 423 is logically high when its source terminal 425 is at ground voltage. When the voltage at the source terminal 425 of the MOS transistor 428 is pulled below ground through the gate 405 of the LDMOS 402, its drain terminal 423 also flips its logic state to low, e.g., 0, indicating a zero voltage crossing at of the HS terminal 110 has been detected. The ZVS unit 130 then outputs a ZVS_out signal via driver 432 based on the voltage at drain terminal 423 of the MOS transistor 428.

In the example of FIG. 1, the bootstrap capacitance charger 120 further includes a pair of ZCS/OCP units 132_1 and 132_1 each associated with one of the FETs 102 and 104, respectively, wherein each ZCS/OCP unit 132 is integrated on the silicon substrate/die and capable of detecting ZCS and/or OCP condition at the FETs. In one example, each ZCS/OCP unit 132 utilizes an insulated LDMOS device as a sense FET for both ZCS and OCP detection at the switching terminal 110.

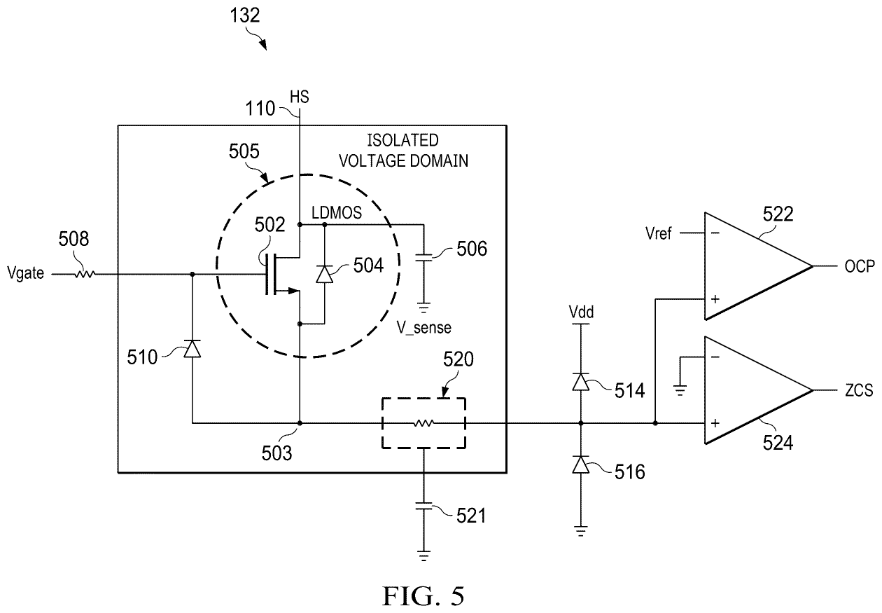

FIG. 5 depicts an example of a schematic diagram of the ZCS/OCP unit 132 associated with each of the FETs of the bridge driver 100 of FIG. 1. As shown in the example of FIG. 5, the ZVS unit 132 includes a LDMOS 502 with its drain terminal connected to the switching terminal (HS) 110 shown in FIG. 1. In one example, the LDMOS 502 has a body-diode 504 between its drain terminal and source terminal and a capacitor 506 coupled between the drain terminal of the LDMOS 502 and ground. In one example, the sensing LDMOS 502 is switching in sync with the FET (102 or 104) the ZCS/OCP unit 132 is associated with, wherein the sensing/source terminal 503 of LDMOS 502 is floating during off (low voltage) state and tracks the switching voltage V_{HS} at the switching terminal 110 for ZCS and OCP detection during on (high voltage) state. In one example, the LDMOS device 502 is capable of sensing a voltage Vsense at its source terminal 503 without any parasitic diode to silicon substrate. In one example, gate terminal 505 of the LDMOS 502 is connected to and controlled in sync with the gate voltage Vgate of the FET (102 or 104) the ZCS/OCP unit 132 is associated with through a resistor 508. In one example, the LDMOS 502 allows the switching voltage V_{HS} to swing up to −5V with respect to the substrate voltage Vss without loading the switching terminal 110.

In one example, the sensing LDMOS 502 operates in an isolated voltage domain on the silicon die, wherein all the connected circuits in the isolated voltage domain are protected with suitable voltage clamps. In one example, the ZCS/OCP unit 132 includes a diode clamp 510, e.g., a Zener diode, between the gate terminal 505 to the source terminal 503 of the LDMOS 502. The gate-source diode clamp 510 protects the gate 505 of the LDMOS 502 and the high value resistance 508 isolates the sensing LDMOS 502 from the driver circuit of the FET (102 or 104) the ZCS/OCP unit 132 is associated with. In one example, the source terminal 503 of the sensing LDMOS 502 is also isolated from an OCP comparator 518 and a ZCS comparator 524 by another resistor 520 with a capacitor 521 coupled to the ground. In one example, the low voltage domain of the sensing LDMOS 502 is protected by a diode clamp 514 to Vdd and a diode clamp 516 to the ground (0V), respectively. In one example, both the OCP comparator 518 and the ZCS comparator 524 are current comparators that are capable of outputting an OCP signal and a ZCS signal, respectively. In one example, the OCP comparator 518 and the ZCS comparator 524 each has the same or similar internal configurations and functionalities as the current comparator 422 discussed above. In one example, a voltage level down shifter (LSHDN) 128 in FIG. 1 is capable of transferring the ZVS, ZCS, and OCP signals at a lower voltage (e.g., 200V to 5V) from the high side domain to the low side domain of the bridge driver 100.

The solutions described above enable a generic monolithic bridge driver 100 with ZVS, ZCS and OVP capabilities. As such, the bridge driver 100 can be used independently with FETs of any size and does not need any additional interconnect between the FETs and driver die, thus simplifying the integration of multiple dies inside a package. Furthermore, the bridge driver 100 described above achieves a faster response for IDM operation with the sensing terminal voltage level shifted up to avoid a negative threshold. In addition, the bridge driver 100 is capable of fast ZVS and ZCS detection for a high voltage, e.g., 200V, application with no series component needed for the ZCS and ZVS units.

In this description, the term “coupled” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “capable of” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a capacitor connected between a bootstrap supply terminal (HB) and a switching terminal (HS) of a bridge driver;
an NMOS transistor having its drain terminal and cathode of its body diode both connected to the bootstrap supply terminal;
a pair of PMOS transistors coupled in parallel with shared source and drain terminals, wherein their shared source terminal connects to a first power supply (VDD) at a first power supply terminal, wherein their shared drain terminal connects in series to a source terminal of the NMOS transistor, and wherein cathodes of body diodes of the pair of PMOS transistors connect to the first power supply terminal; and
a charge pump capable of generating a second power supply (VCP) at a second power supply terminal, wherein the second power supply is capable of charging the capacitor via the NMOS transistor and the pair of PMOS transistors at a higher voltage than the first power supply.

2. The apparatus of claim 1, wherein:
the bridge driver is a Gallium Nitride (GaN)-based bridge driver capable of controlling and driving a pair of GaN Field-Effect Transistors (FETs) in a half-bridge configuration.

3. The apparatus of claim 2, wherein:
the capacitor is a bootstrap capacitor capable of driving a high-side GaN FET of the pair of GaN FETs of the GaN-based bridge driver.

4. The apparatus of claim 1, wherein:
the NMOS transistor serves as a reverse-blocking FET that blocks reverse-recovery charge (QRR) to avoid a diode drop during charging of the capacitor.

5. The apparatus of claim 1, wherein:
the pair of PMOS transistors serve as control FETs that control a charging current to the capacitor.

6. The apparatus of claim 1, further comprising:
a control logic capable of generating a signal to drive gates of the pair of PMOS transistors to charge the capacitor.

7. The apparatus of claim 6, wherein:
the control logic is capable of stopping the pair of PMOS transistors from charging the capacitor if there is an over voltage condition at the capacitor.

8. The apparatus of claim 6, further comprising:
a boot-on logic capable of
generating a boot-on signal to start charging the capacitor; and
providing the boot-on signal as input to the charge pump, the control logic, and a level shifter.

9. The apparatus of claim 8, further comprising:
said level shifter capable of generating a level-shifted version of the boot-on signal to drive a gate of the NMOS transistor.

10. The apparatus of claim 8, wherein:
the boot-on signal goes high at beginning of a first dead time of a switching signal at the switching terminal, wherein the switching signal goes negative during the first dead time of the switching signal at the switching terminal.

11. The apparatus of claim 10, wherein:
the boot-on signal goes low at beginning of a second dead time of the switching signal at the switching terminal, wherein the switching signal goes negative during the second dead time of the switching signal at the switching terminal.

12. The apparatus of claim 1, wherein:
a first PMOS transistor and a second PMOS transistor of the pair of PMOS transistors have different strength and/or threshold voltages.

13. The apparatus of claim 12, wherein:
only one of the pair of PMOS transistors is turned on to charge the capacitor under certain circumstance.

14. An apparatus comprising:
a capacitor connected between a bootstrap supply terminal (HB) and a switching terminal (HS) of a bridge driver;
a charge pump capable of generating a second power supply at a higher voltage than a first power supply at a power supply terminal (VCP), wherein the second power supply is capable of charging the capacitor via a NMOS transistor and a pair of PMOS transistors connected in series with the NMOS transistor; and
a control logic capable of controlling charging of the capacitor via the pair of PMOS transistors.

15. A method, comprising:
generating a second power supply at a higher voltage than a first power supply at a power supply terminal;
utilizing the second power supply to charge a capacitor connected between a bootstrap supply terminal (HB) and a switching terminal (HS) of a bridge driver via a NMOS transistor and a pair of PMOS transistors connected in series with the NMOS transistor;
generating a boot-on signal to start charging the capacitor; and
controlling charging of the capacitor via the NMOS transistor and the pair of PMOS transistors according to the boot-on signal.

16. The method of claim 15, further comprising:
driving a high-side Gallium Nitride (GaN) FET of a pair of GaN Field-Effect Transistors (FETs) of a GaN-based bridge driver via the capacitor.

17. The method of claim 15, further comprising:
stopping charging the capacitor if there is an over voltage condition at the capacitor.

18. The method of claim 15, wherein:
wherein the boot-on signal goes high at beginning of a first dead time of a switching signal at the switching terminal, wherein the switching signal goes negative during the first dead time of the switching signal at the switching terminal.

19. The method of claim 18, wherein:
the boot-on signal goes low at beginning of a second dead time of the switching signal at the switching terminal, wherein the switching signal goes negative during the second dead time of the switching signal at the switching terminal.

20. The method of claim 15, further comprising:
generating a level-shifted version of the boot-on signal to drive the NMOS transistor.

21. The method of claim 15, wherein:
a first PMOS transistor and a second PMOS transistor of the pair of PMOS transistors have different strength and/or threshold voltages.

22. The method of claim 21, further comprising:
turning on only one of the pair of the pair of PMOS transistors to charge the capacitor under certain circumstance.
